(19) United States
(12) Patent Application Publication
(10) Pub. No.: US 2024/0195168 A1
(43) Pub. Date: Jun. 13, 2024

(54) METHOD AND CONTROL CIRCUIT FOR OPERATING A SWITCHING ELEMENT OF AN ELECTRICAL COMPONENT IN ORDER TO AVOID OVERHEATING BY ELECTRICAL DISSIPATED HEAT, AND AN ELECTRICAL COMPONENT HAVING THE CONTROL CIRCUIT

(71) Applicant: CARIAD SE, Wolfsburg (DE)

(72) Inventors: Ronny HERMS, Gardelegen (DE); Michael KIFFMEIER, Gifhorn (DE); Oliver BETTGENS, Danndorf (DE); Maximilian GAJECK, Magdeburg (DE)

(21) Appl. No.: 18/526,919

(22) Filed: Dec. 1, 2023

(30) Foreign Application Priority Data
Dec. 7, 2022 (DE) 102022132531.8

(51) Int. Cl. H02H 5/04; G01R 19/00; G01R 19/02; H02H 3/093

(52) U.S. Cl. CPC H02H 5/041; G01R 19/003; G01R 19/02; H02H 3/093; H02H 5/047

(57) ABSTRACT

The disclosure relates to a method for operating a switching element of an electrical component, which includes: providing a time series of current strength values of an electrical current flowing in the electrical component registered in time steps that are consecutive, the electrical current being led through the switching element, operating a thermal model of the electrical component, determining a temperature of the electrical component from the current strength values using the thermal model and, in response to determining that the temperature is greater than a limit value, switching the switching element to an electrically blocking state in which the current is interrupted. The disclosure thermal model is a first order recursive filter that filters squared current strength values of the time series and generates, as a respective output value in each of the time steps, a presently estimated temperature value Tₙ that is compared to the limit value.

### BACKGROUND

### Technical Field

The disclosure relates to a method and a control circuit for safeguarding and monitoring an electrical line or some other electrical component having a controllable switching element. The method constantly computes a present temperature in the electronic component and controls the switching element to safeguard the component against overheating. The disclosure also provides a correspondingly safeguarded electrical component, such as a cable (electrical line) having a switching element.

### Description of the Related Art

Until now, electrical conduits have been protected against thermal overload due to high current loads by melting fuses. An electrical conduit is protected by melting a fuse. At present, electronic fuses are being used for electrical conduit protection. Their triggering behavior is oriented directly to the conductor isotherm of the electrical conduit and is known as the i²t method. The conductor isotherm describes the permissible current pulse length and current pulse height in a time/current diagram in order to heat the electrical conduit from a starting temperature to a still permissible conduit temperature. In the procedure, often called the i²t or RMS (RMS—root mean square) method, the effective value of a measured current flow through the electrical conduit being measured is determined continuously over a particular time interval. In practice, the effective values of the current profile are determined within time intervals of different length and compared with corresponding established maximum permissible limit values oriented to the conductor isotherms, the response being a disconnection. This is only an averaging method and hence there must be a definite safety interval from the conductor isotherms.

A safeguarding of an electrical conduit by way of a controllable switching element is known from DE 10 2009 027 387 B4. From DE 10 2014 200 946 C5 it is known how to define conductor isotherms by way of a current/time characteristic diagram which indicate how long a current can flow in a given electrical line before it is heated up to a given temperature. The use of such a characteristic diagram to control a controllable switching element is described in DE 10 2019 131 533 A1. A modeling of this heating is known from EP 1 850 438 B1 and US 2018/0034259 A1. From US 2019/0165564 A1 it is known that the time/current characteristic can furthermore take account of the ambient temperature.

It has been found that the use of the models known from the prior art to determine a present temperature of an electrical conduit or in general an electrical component requires the computation of mathematical integrals in order to ascertain all of the thermal energy present in the component over time. Accordingly, such a monitoring is hungry in computer and memory resources to implement the mathematical integration digitally. Furthermore, the integration over a time interval produces a corresponding inertia in regard to the estimation of the present temperature value, which can result in a delayed response time of the electronic fuse in the case of abrupt changes in the current strength, such as a short circuit.

A scientific publication by Önal and Frei (Selcuk Önal, Stephan Frei, “A model-based automotive smart fuse approach considering environmental conditions and insulation aging for higher current load limits and short-term overload operations,” 2018 IEEE International Conference on Electrical Systems for Aircraft, Railway, Ship Propulsion and Road Vehicles & International Transportation Electrification Conference (ESARS-ITEC)) describes a model simulating the heat dissipation in an electrical cable and an electrical insulation.

### BRIEF SUMMARY

Embodiments of the disclosure provide protection against overheating of an electrical component, such as may occur on account of the current flow of an electrical current in the electrical component.

As one solution, the disclosure teaches a method for operating a switching element of an electrical component, including:
providing a time series of current strength values of an electrical current flowing in the component that were registered in consecutive time steps, the current being led through the switching element, and
operating a thermal model of the component with the current strength values and
determining a temperature of the component from the respective present current strength value by way of the thermal model and
in the event that the temperature is greater than a predetermined limit value, switching the temperature protection circuit to an electrically blocking state in order to interrupt the current.

As the electrical component it is possible to monitor, e.g., a cable or a conductor track or in general an electrical line, such as can be provided in the power electronics of a motor vehicle. In general, the electrical component may comprise a device and/or an electrical line. In known manner, upon overheating of the component, i.e., at a temperature above the limit value, the electrical current responsible for the production of the heat should be interrupted by way of a controllable switching element. Thus, this requires an electronic or electrical fuse. Instead of a temperature measurement by way of a temperature sensor, the current strength of the current is monitored, as known from the aforementioned prior art, and from this a thermal model is used to estimate or deduce the temperature which must be present in the component. The current strength is updated or signaled as a time signal or as a time series of measurement values at each time step. These measurement values are designated here as current strength values. The current strength of the current can be measured for this, directly or indirectly, through an auxiliary variable, such as an electrical voltage drop across a shunt resistor, in known manner. A measurement principle from the prior art can be used for this.

In order to implement the estimation or computation of the temperature economically in terms of computer resources and/or with fast response in a corresponding control circuit for the switching element, the disclosure proposes that the thermal model comprises a recursive filter of first order, which filters or processes the squared current strength values of the time series and generates, as the respective output value for the temperature in each time step, the presently estimated temperature value Tₙ, which is compared in the described manner to the limit value. The index n here is in customary fashion the time index, i.e., the ordering number of the time steps. Starting with the current strength values registered up to a time n, their squared value is used, which is a measure of the electrical power carried by the current in the component. Since the current strength values are registered and/or determined as a time series, i.e., consecutively in time, the squared current strength values also yield a corresponding time series, which is processed or filtered by way of the recursive filter. Thus, the temperature value Tₙ can be determined for each unit of time. So while the time series of current strength values is received for current strength values, in parallel with this the present temperature value Tₙ can be computed for each time step n.

The use of a recursive filter of first order affords the advantage that it is only necessary to save the estimated temperature value of the preceding time step n−1, i.e., the temperature value Tₙ₋₁, which can be implemented more efficiently than a numerical integral for the squared current strength values of an entire preceding time window with more than one preceding time step. In this way, a recursive filter of first order is faster in its response, since it causes little or no averaging effect.

The parameter values of the parameters of the recursive filter of first order can be determined analytically in the following described manner by modeling of a cooldown process of the electrical component or a machine learning method, for example, can be provided to determine suitable parameter values for the parameters of the recursive filter or it is possible to use a method known in the prior art to estimate parameter values of a recursive filter. One generic form of a recursive filter, as an example, is the following:

Tₙ=P₁Tₙ₋₁+P₂

Where the two parameters P₁ and P₂ are the parameters whose values are to be adapted to the temperature behavior of the given or monitored electrical component.

The disclosure also encompasses modifications which produce additional benefits.

One modification proposes that the filter contains a (mathematical) term for a power input, which quantifies the electrical power that is produced by the present squared current strength value i²ₙ of the present time step n. Since the current is flowing continuously, i.e., a current strength i(t) is flowing through the component during the time t, the component becomes heated on account of its ohmic resistance R to the electrical current i, so that at every point in time the following heating power is realized in the component:

P_{warm}=Ri²(t)

Which can be used in the thermal model to determine the electrical power introduced or added during the time step n and thus to determine the resulting heating or thermal energy. By discretization of the time function i(t) into the time steps n, one obtains a time series of energy inputs which are realized with each new time step in the component or produce a heating there. Thus the newly added thermal energy from the present time step n is computed by the term for the power input in the recursive filter.

One modification proposes that the filter contains a (mathematical) term for a heat dissipation from the electrical component, and the heat dissipation results from a characteristic value rₜₕ for a thermal resistance of a material of the component. This term takes into account the self-cooling or escape of heat from the component, which can likewise be factored into a recursive filter by computing the heat dissipation or cooldown capacity, i.e., the heat given off by the component to the surroundings, starting with the temperature of the preceding time step n−1. In this way, it is advantageously possible to also simulate a cooldown process which may last for multiple time steps by way of the filter of first order.

One modification proposes that the filter contains a (mathematical) term with an ambient temperature Tᵤ at the present time step n, i.e., Tᵤₙ, the value of which is provided from measured values of the ambient temperature. The ambient temperature can be detected in known manner by way of a temperature sensor. Factoring in the ambient temperature affords the benefit that the thermal model will consider that the component, without a supply of current or without a current flow, will cool down to the ambient temperature and not below this.

One modification proposes that the filter contains at least one (mathematical) term normalized to a sampling rate f of the time series, wherein the sampling rate is f=1/Δt and Δt is the respective time duration of the time steps. In other words, consideration is given to how large or how long-lasting the particular time step is. In this way, one advantageously prevents a scaling or an offset from occurring in the computation of the temperature values due to a changing of the clock rate or sampling rate with which the current strength values are registered. In other words, the filter becomes self-adaptive in regard to the sampling rate. The sampling rate can be dictated or memorized in a data storage as a configuration value. Thus, the sampling rate can also be described by Δt in the filter.

One modification proposes that the filter models a temperature-dependent material property of a material of the component and uses the output value Tₙ₋₁ of a preceding time step as the present temperature of the material. In other words, the filter is also adaptable or flexible in that a property of the material, such as the thermal resistance and/or the ohmic resistance, can take on a temperature-specific value over the course of time, depending on the present temperature. This can be taken into account in the filter by using the last computed output value Tₙ₋₁ as the temperature value. This is a sufficiently precise approximation, as has been observed in simulations.

One modification proposes that the filter comprises specific parameters, each of which indicates a length-related dimension. In other words, regardless of the absolute length or the absolute longitudinal extension, the temperature is computed with parameters pertaining to length-related dimensions, such as resistance per meter. In this way, it is not necessary to consider the geometry in the longitudinal direction of the component in the filter, which is of special advantage in particular when estimating the temperature in a cable or generally in an electrical line. In the case of short cables, this can result in an overestimation of the temperature, because a cooldown effect is not modeled at the terminals. Yet the overestimation has proven to be an advantageous additional component protection in practice.

One modification proposes that the filter comprises as the parameters of the component:
rₜₕ: specific thermal resistance
σ: electrical conductivity
A: cross section area
ρ: specific gravity
c: specific heat capacity
   and the filter computes the output value Tₙ for the time steps n as:

$${T}_{n} = \frac{{T}_{un} + \frac{σ {r}_{th}}{A} {i}_{n}^{2} + c ρ {Ar}_{th} f {T}_{n - 1}}{1 + c ρ {Ar}_{th} f} with n = 1 , 2 , …$$

with T₀=Tᵤ₀ being the initial ambient temperature Tᵤ and Tᵤₙ being the ambient temperature Tᵤ measured at the respective time step n.

The deriving of this filter is described more closely in the following in connection with the exemplary embodiment. The proposed filter has the advantage of bringing together the already described benefits. The time step n=0 is the last time step before switching on the current, so that it can be assumed here that the component has the ambient temperature Tᵤ.

One modification proposes that a heat storage capacity of an electrical Insulation of the component and that of a material k of the component surrounded by this and electrically conducting the current is factored into the filter by

cρA=cₖρₖAₖ+cᵢρᵢAᵢ.

The subscripts i for the insulation and k for the electrically conductive component material distinguishing the respective characteristic values (specific heat capacity c, specific gravity p and cross section area A measured transversely to the current flow direction) are only two exemplary quantities, and further material properties can also be taken into account, for example, in the case of a multilayered insulation, since this can be additively continued, as shown, especially by way of specific parameters (length-related dimensions). Thus, the different cooldown behavior or the different heat dissipation in the different materials can be taken into account by the filter. One modification proposes that a cable is monitored as the electrical component, such as usually comprises the described insulation.

One modification proposes that an electronic semiconductor switch is actuated as the switching element. An electronic switch can be switched reversibly by way of a control signal between the electrically conducting and the electrically blocking state. In other words, the switching element after an interruption of the current can advantageously be switched back to the electrically conductive state in order to place the component back in operation. The electronic semiconductor switch which is used can be for example a transistor, especially a FET (field-effect transistor), such as a MOS-FET (MOS—metal oxide semiconductor).

For application cases or application situations which may occur in the method and which are not explicitly described here, it can be provided that an error message and/or a prompt to enter user feedback will be put out according to the method and/or a standard setting and/or a predetermined initial state will be established.

As a further solution, the disclosure proposes a control circuit for controlling a switching element of an electrical component, wherein the control circuit is adapted to carry out a method according to the present disclosure. The control circuit for this can comprise at least one microprocessor and/or at least one microcontroller and/or at least one FPGA (Field Programmable Gate Array) and/or at least one DSP (Digital Signal Processor). Furthermore, the control circuit can contain program code which is adapted to carry out the embodiment of the method according to the disclosure when executed by the control circuit. The program code can be kept in a data storage of the control circuit. The processor circuit of the control circuit may comprise, e.g., at least one circuit board and/or at least one SoC (System on Chip).

As a further solution, the disclosure proposes an electrical component having a switching element and having a control circuit according to the disclosure coupled to the switching element. Such a component may comprise, for example, an electrical conduit, such as a cable and/or an electrical power supply network and/or a current busbar, such as may be provided for example in an electric vehicle. The component can be advantageously protected efficiently against overheating through heat input from an electrical current on the basis of the described method.

The component can be provided in a motor vehicle, e.g., in an electric vehicle. The motor vehicle according to the disclosure is preferably configured as an automobile, especially a passenger car or a truck, or as a passenger bus or motorcycle.

The disclosure also encompasses combinations of the features of the described embodiments. Thus, the disclosure encompasses realizations having a combination of the features of several of the described embodiments, as long as the embodiments were not described as being mutually exclusive.

### BRIEF DESCRIPTION OF THE SEVERAL VIEWS OF THE DRAWINGS

Exemplary embodiments of the disclosure are described in the following.

FIG. 1 shows a schematic representation of one embodiment of the component according to the disclosure;

FIG. 2 shows a sketch to illustrate the production of heat in the component, especially when electrical insulation is present;

FIG. 3 shows a signal flow chart of a first embodiment of a recursive filter;

FIG. 4 shows a diagram with schematized variations of measured quantities;

FIG. 5 shows a diagram with schematized variations of power isotherms;

FIG. 6 shows a diagram of a signal flow chart of another embodiment of a recursive filter; and

FIG. 7 shows a diagram with schematized variations of temperature signals that were registered with different methods.

### DETAILED DESCRIPTION

In the exemplary embodiments, the described components of the embodiments each time represent individual features of the disclosure, to be viewed independently of each other, and modifying the disclosure independently of each other. Therefore, the disclosure will also encompass other than the represented combinations of features of the embodiments. Furthermore, the described embodiments can also be supplemented by other of the already described features of the disclosure.

In the figures, the same reference numbers each time denote functionally identical elements.

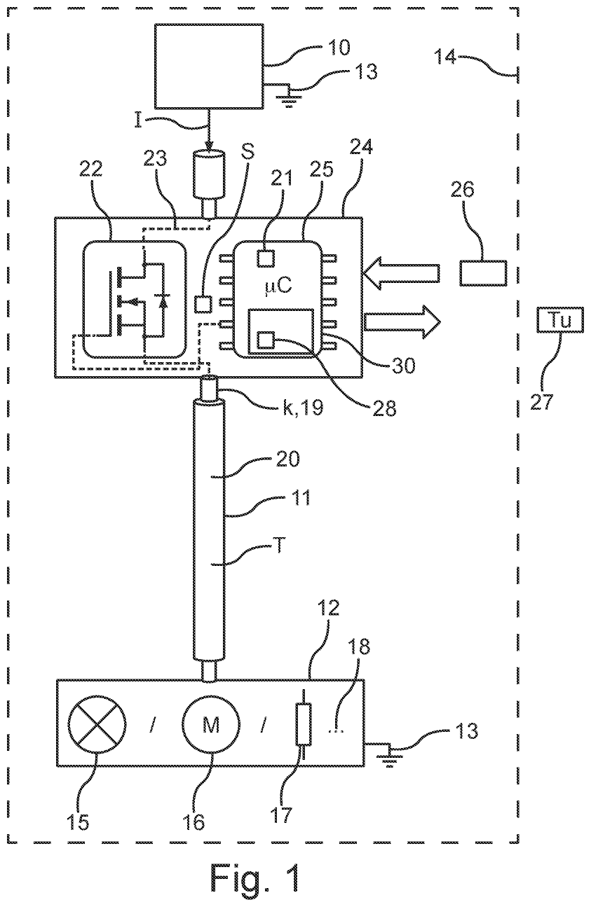

FIG. 1 shows an electrical circuit, in which an electrical current I flows from a source 10 across an electrical component 11 to an electrical consumer 12. It is shown here symbolically that the circuit can be closed across a ground potential 13. For example, the electrical circuit can be provided in a motor vehicle 14, such as being part of an electrical drive. For example, the source 10 may comprise a traction battery and/or a generator. The consumer 12 might be, for example, as shown symbolically in FIG. 1, a light 15 and/or an electrical machine 16 and/or a heating resistor 17, to mention only some examples, being symbolized in the figure by ellipsis 18. The electrical component 11 can be a cable, for example, through which the current I is taken from the source 10 to the consumer 12. It is shown that the cable can comprise an electrically conductive material k as its core 19, which can be [enclosed] by an electrical insulation 20 made from an electrically insulating material. The component 11 may be a cable such as is known from the prior art.

Due to the transmission of the current I through the component 11, it may become heated because of dissipated heat due to the ohmic resistance of the component 11 in the electrically conductive material in the core 19. For example, the material might be copper or aluminum. In the event that a temperature T in the component 11 lies above a limit value 21, it can be provided that a switching element 22 is switched from an electrically conducting state, in which the current I can flow or be taken through the component 11, to an electrically blocking state, in which the current flow of the current I through the component 11 is interrupted or blocked. The switching element 22, for example, may comprise a MOS-FET and/or an IGBT (Insulated Gate Bipolar Transistor). The current I can be taken through the switching element 22; in the case of a transistor, it can be taken through the switching section of the transistor. A corresponding current path 23 is symbolized in FIG. 1.

For the control of the switching element 22, a control circuit 24 can be provided, which can monitor the limit value 21, by way of a processor circuit 25, such as a microcontroller, and upon reaching the limit value 21 by the temperature T it switches the switching element 22 from the electrically conducting to the electrically blocking state. The control circuit 24 together with the switching element 22 can be designed overall as an electronic fuse to protect against a current surge or an overheating of the component 11. Instead of this, the processor circuit 25 can operate an estimation algorithm or an estimation method to determine the present value of the temperature T. For this, in addition to or alternatively to a microcontroller, an ASIC (Application Specific Integrated Circuit) for example can also be provided for the temperature computation and/or a signal processing.

Through the control circuit 24, a state signal 26 can be sent to at least one other control circuit or at least one other controller, for example in the motor vehicle 14. The state signal 26 can report the switching state of the switching element 22, the electrical voltage U and/or the current strength value of the current I as measured by the control circuit 24, and/or the estimated temperature T of the cable or the conduit or the component 11 in general. For the control of the operating state of the control circuit 24, a control signal 27 can be received by the control circuit 24. Through the control signal 27, the ambient temperature T_{U} can be reported to the control circuit 24, which can be used when estimating or computing the temperature value 28 of the temperature T. For this, a thermal model 30 can be used by the control circuit 24, as shall be further described below. The transmission of the state signal 26 and/or the control signal 27 can be done for example through a data bus (such as a CAN—controller area network) and/or an Ethernet network.

The processor circuit 25 can generate, for example, a switching signal S for the controlling or switching of the switching element 22, if the temperature T exceeds a given limit value, such as a limit value in the range of 90° C. to 150° C.

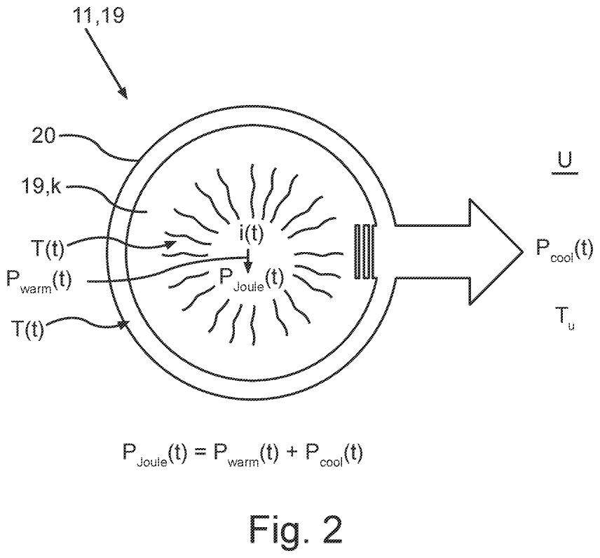

FIG. 2 illustrates how a thermal model 30 can be determined, as an example. For this, the component 11 is represented as a cable in FIG. 2. A cross section perpendicular to the flow direction of the current I shall be considered. The current I here is considered to be a time signal i(t). Due to the current flow of the current through the electrically conducting material k of the core 19 of the cable, i.e., copper or aluminum, for example, a heating power P_{warm}(t) is produced on account of the ohmic resistance of the material as a time signal over the time t, corresponding to the heat introduced or generated in the cable at every moment of time. This corresponds to a power input of electrical power, which is transformed or converted into heat. A portion of this heat can be given off as heat dissipation P_{cool}(t) to the surroundings U of the component 11. In the surroundings U, it can thus be assumed that the ambient temperature Tᵤ prevails. From the balance of the power input of the heating and the cooldown by heat dissipation, one gets the joulian heat P_{Joule}(t), which is the cause of the present temperature T(t) at the particular moment of time t.

Since this modeling is based on a cross section, length-related specific characteristic values can be used advantageously for the modeling.

On the basis of such a modeling, and by discretization of the time t into time steps n by sampling with a sampling rate f at corresponding moments of time with a time interval of Δt, one gets discrete time points n=1, 2 . . . , at each of which a present temperature wert Tₙ can be computed.

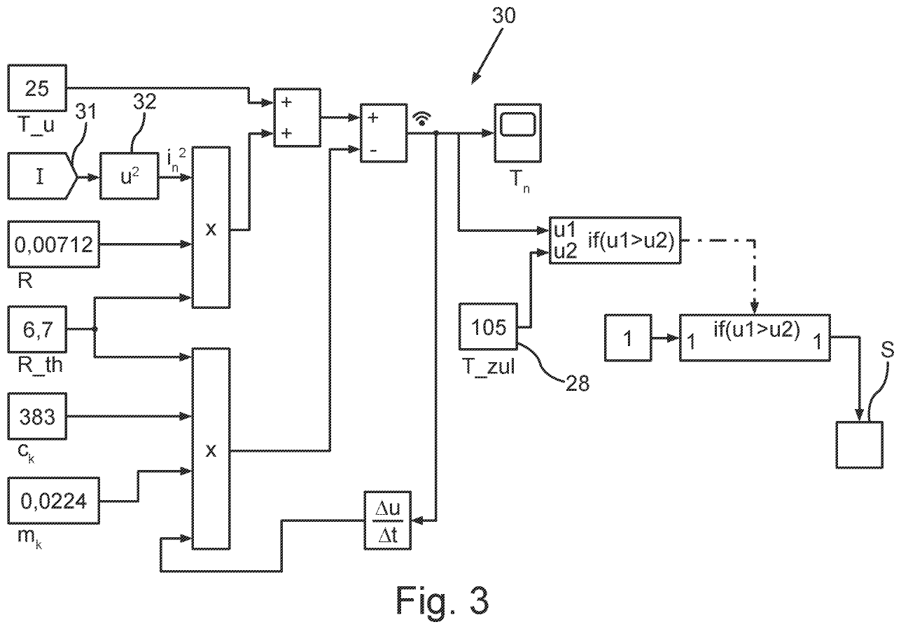

FIG. 3 shows one possible thermal model 30 in a representation of the conduit cross section, disregarding the insulation given thin insulating layers, the thermal balance from the generation of heat in the conductor, the heating of the conductor, and the heat given off to the surroundings.

In this idea, the conduit temperature is thus determined as an approximation or estimation in real time of the current I flowing at the moment through the conductor, and the switching of the switching element is regulated to this. It can be assumed from the power balance represented in FIG. 2 that the joulian power loss P_{Joule}(t) occurring at time t passes in part into the heating of the conduit P_{warm}(t) and in another part to the heat given off to the surroundings P_{cool} (t). We have P_{Joule}(t)=P_{warm}(t)+P_{cool}(t) and specifically

$${Ri}^{2} ( t ) = c m \frac{dT ( t )}{dt} + \frac{1}{{R}_{th}} ( T ( t ) - {T}_{u} ) \qquad ( 1 )$$

(R—electrical resistance, c—specific heat capacity, m—conductor mass, Rₜₕ—thermal resistance to the surroundings, T—temperature, Tᵤ—initial and ambient temperature).

For the method converted to

$${T}_{u} + R {R}_{th} {i}^{2} ( t ) - c m {R}_{th} \frac{dT ( t )}{dt} = T ( t ) . \qquad ( 2 )$$

The method, shown schematically in FIG. 3, functions as follows: starting from the initial and ambient temperature Tᵤ, the current i measured with the given sampling rate at time t is squared and multiplied by the constants for the thermal resistance Rₜₕ and the ohmic resistance R. From this result at time t is subtracted the product of the material properties: the specific heat capacity c, the conductor mass m and the thermal resistance Rₜₕ with the quotient of the temperature change ΔT and the time step increment Δt, starting from the previous time point. The present temperature determined from this is compared to the permissible temperature for the conduit. If it is attained, the electronic switching element is activated, the current flow is interrupted, and the conduit is protected against overheating. The method works with minimal arithmetic operations, as compared to the RMS method, with its many RMS computation procedures. Only 5 arithmetic operations need to be performed.

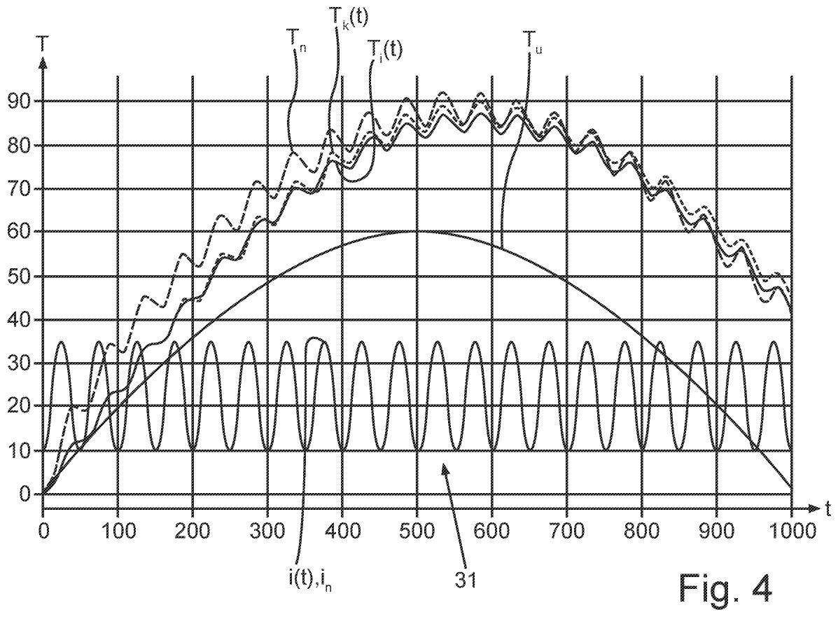

FIG. 4 illustrates the functioning of the thermal model of FIG. 3. For the time t in seconds, temperature values of the temperature T and a time variation of the current i(t) are plotted. There is shown a variation of the temperature Tc(t) of the electrically conducting material, such as copper, and the temperature of the insulation material Ti(t). Furthermore, a time variation of the ambient temperature Tu is shown. The discretized variant of the current function i(t) made up of single measurement values or sampled values produces a time series in, which can be generated as a time series 31 by sampling of a current strength sensor or a current strength signal and which can be used (as shown in FIG. 3) as input for the model 30. From this, by squaring 32, squared current strength values iₙ² can be generated.

The time series of the estimated temperature values Tₙ is shown in FIG. 4 as compared to the true temperature value T(t). For comparison, a method Ti(t) used in the prior art is likewise shown.

Deviations noticeable in FIG. 4 result from the simplifications in equation (1), the disregarding of the insulation, its thermal mass, and the thermal resistance to the surroundings. A further simplification is the combining of the thermal convection and thermal radiation to produce one thermal resistance to the ambient temperature. The deviations are larger in the case of rapid current changes. The method has the major advantage of responding to changing ambient temperatures, cf. FIG. 4, by adapting the input quantity Tᵤ to the surrounding conditions. The Tᵤ value from one of the temperature sensors present in the region of the conduit being protected can be used. Thus, the method has the potential of economizing on copper material, since the conduit cross section can be better utilized without any unnecessary reservation.

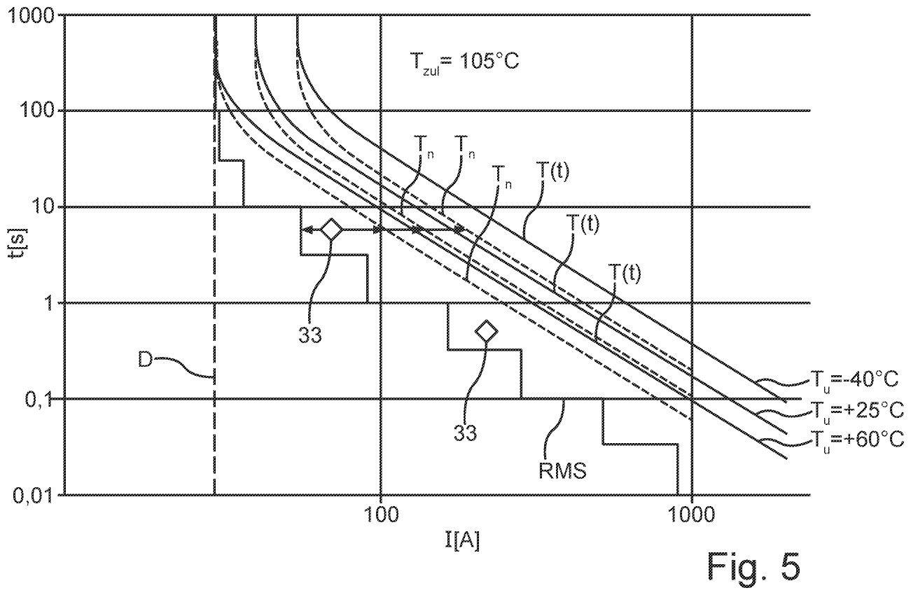

FIG. 5 shows characteristic curves for determining the permissible current strength values or current pulses plotted against the current strength I in ampere and the time t in seconds as the ordinate, where a limit value T_{zul} of 105° C. results, so that the current I in the component 11 is interrupted by switching of the switching element 22. There are shown the true function T(t) of the isotherms of T_{zul}=105° C. and the value Tₙ calculated for this from the thermal model 30. For a comparison, an estimate by way of a RMS method is shown, such as is known in the prior art. For example, two operating points 33 are illustrated, showing that an interruption of the current flow of the current I would already be triggered or undertaken by way of the RMS method, while it is recognized by the thermal model 30 that the limit value T_{zul} of 105° C. has not yet been reached in this example at these operating points 33. For a further illustration, the long-term current limit or the long-term current value D is also shown, at which the power input is equalized by the current strength and the heat dissipation.

Furthermore, FIG. 5 makes a comparison of the RMS method with the new method. The RMS limit values have to cover the entire temperature operating range and need to be designed for the ambient temperature occurring up to 60° C. A sample consumer with a current demand in the form of a pulse height of 60 A and a pulse width of 5 s can no longer be protected with the RMS method, and a larger conduit cross section would need to be used. The newly proposed method makes it possible to reconcile the sample working points in FIG. 5 with the 2.5 mm² conduit.

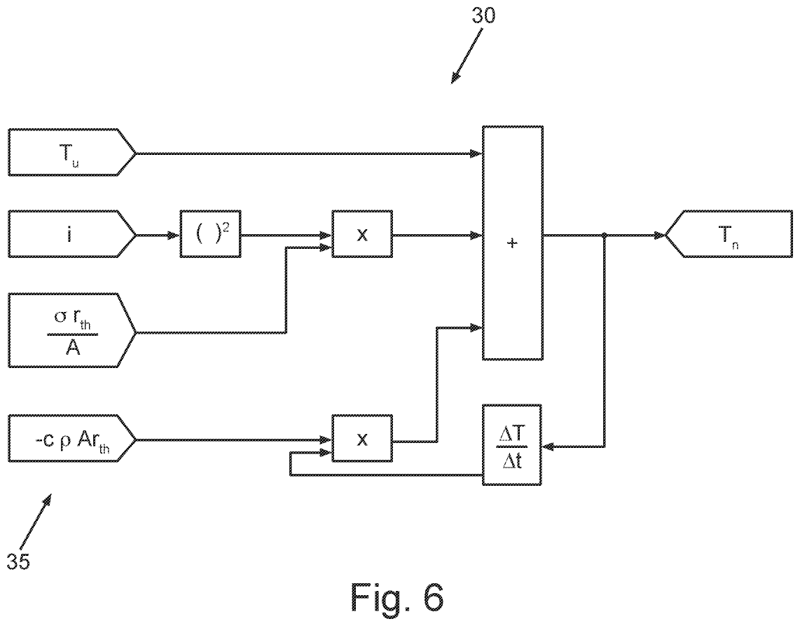

FIG. 6 illustrates a further embodiment of the thermal model 30, in which length-related specific parameters 35 are used as input values for computing the estimated temperature value Tₙ.

Only the Rₜₕ values would need to be determined for the different conductor cross sections A relative to one meter of length 1. Through the quasi-stationary state, i.e., joulian thermal power in equilibrium with the thermal power given off to the surroundings, i.e., with no further conductor heating.

With

$$R = σ \frac{l}{A} , m = ϱ Al and {r}_{th} = {R}_{th} l \qquad ( 3 )$$

the differential equation (2) can be formulated more user-friendly as

$$Tu + \frac{σ {r}_{th}}{A} {i}^{2} ( t ) - c ϱ {Ar}_{th} \frac{dT ( t )}{dt} = T ( t ) , \qquad ( 4 )$$

where rₜₕ is used as the thermal resistance relative to one meter. FIG. 6 shows for example the procedure residing in a microcontroller of the processor circuit.

For the practical implementation of the method, equation (4) must be represented in discrete form. With a defined sampling rate, here taken as the frequency f=1/Δt, the measured current values in and the present ambient temperature T_{u,n} are available for use. The arithmetic procedure can thus be formulated as

$${T}_{u , n} + \frac{σ {r}_{th}}{A} {i}_{n}^{2} - c ϱ A {r}_{th} ( {T}_{n} - {T}_{n - 1} ) f = {T}_{n} \\ n = 1 , 2 , … \qquad ( 5 )$$

If equation (5) is converted to Tₙ, one gets the arithmetic procedure which can be implemented in the electrical fuse

$$\frac{{T}_{u , n} + \frac{σ {r}_{th}}{A} {i}_{n2}^{} - c ϱ A {r}_{th} {fT}_{n - 1}}{1 + c ϱ A {r}_{th} f} = {T}_{n} \\ n = 1 , 2 , … \qquad ( 6 )$$

At the start of the first computation n=1, Tₙ₋₁ is set at T₀=T_{u,0}, i.e., the initial temperature is equal to the ambient temperature.

It should be noted that somewhat higher temperature is determined when using this new method for relatively short conduits. Conduit terminals with crimp connections, for example, may constitute temperature sinks and the actual conduit temperature may be lower than that determined through the method.

In the case of conduits with small copper cross sections, the proportion of insulation in the total cross section is larger. Then for better accuracy the thermal mass of the insulation can be included in equation (6).

With c [symbol] A=c_{K} [symbol] _{K}A_{K}+c_{I} [symbol] _{I}A_{I}, the procedure can be further expanded in order to describe more accurately the heating phase.

$$\frac{{T}_{u , n} + \frac{σ {r}_{th}}{A} {i}_{n}^{2} + ( {c}_{K} {ϱ}_{K} {A}_{K} + {c}_{1} {ϱ}_{1} {A}_{1} ) {r}_{th} {fT}_{n - 1}}{1 + ( {c}_{K} {ϱ}_{K} {A}_{K} + {c}_{1} {ϱ}_{1} {A}_{1} ) {r}_{th} f} = {T}_{n} , n = 1 , 2 , … \qquad ( 7 )$$

No temperature dependencies were used for the material properties used in equation (6), since it is sufficient for an estimation of the temperature to use the values of the material properties in the region below the limit temperature where the electronic switch is to be triggered. The procedure can be expanded even further with σ=σ_{20° C.}+α(Tₙ₋₁−20° C.), in order to allow for the joulian losses even more accurately throughout the relevant temperature range.

$$\frac{{T}_{u , n} + \frac{( {σ}_{20 ° C .} + α ( {T}_{n - 1} - 20 ° C . ) ) {r}_{th}}{{A}_{K}} {i}_{n}^{2} + ( {c}_{K} {ϱ}_{K} {A}_{K} + {c}_{1} {ϱ}_{1} {A}_{1} ) {r}_{th} {fT}_{n - 1}}{1 + ( {c}_{K} {ϱ}_{K} {A}_{K} + {c}_{1} {ϱ}_{1} {A}_{1} ) {r}_{th} f} = {T}_{n} \\ n = 1 , 2 , … \qquad ( 8 )$$

In the following, the safeguarding of a 0.5 mm² line having a large insulation/conductor cross section ratio is presented. The material properties of conductor and insulator have been taken into account:

Stranded copper wire: σ=0.0178 Ωμm, [symbol] =8960 kg/m³, A=0.5 mm², c=383 J/(kg K)

PVC insulation: [symbol] =1380 kg/m³, d=0.5 mm (Insulation thickness), A=2.04 mm², c=1800 J/(kg K).

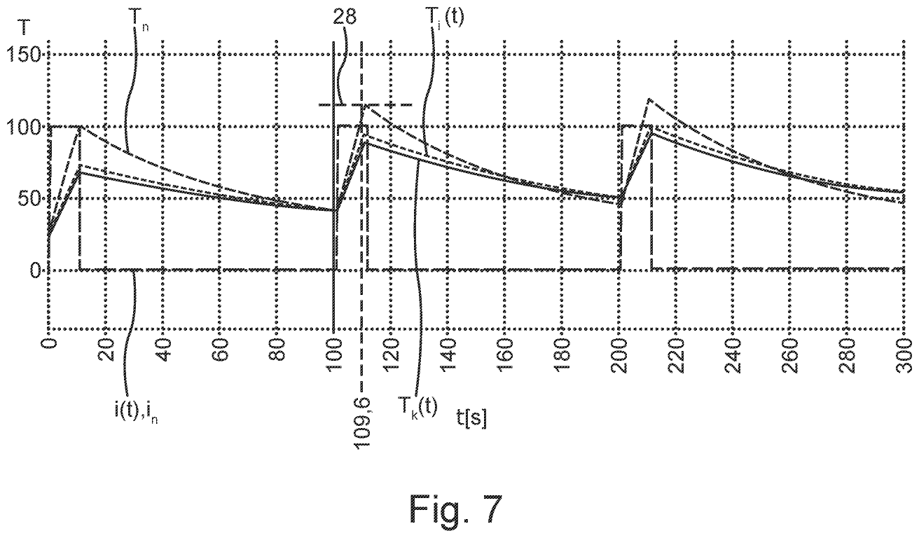

FIG. 7 illustrates in comparable manner to FIG. 4 a further measurement. In FIG. 7, for comparison with the estimated temperature values Tₙ, once again the temperature of the electrically conductive material Tₖ(t) and that of the insulation Tᵢ(t) are represented, such as can be determined for example by way of a simulation. An ambient temperature Tᵤ of 25° C. has been assumed. The figure shows how the thermal model 30 overestimates the true temperature, which provides a further protection for the component 11. Even so, the limit value T_{zul} of 105° C. is not surpassed, so that the current flow here is not interrupted, while in the case when a RMS method is used (see FIG. 5) an operating point would be reached at which a RMS method would cause an interruption of the current for the represented current flow i(t). FIG. 7 shows the practicable working of the method in the case of pulsed currents. Upon heating of the line by the sudden current pulse, the temperature is always somewhat overestimated and thus provides a kind of safety reserve at the same time.

On the whole, the examples show how an electronic fuse with real-time temperature determination can be provided for monitoring and safeguarding of electrical components against thermal overload.

German patent application no. 102022132531.8, filed Dec. 7, 2022, to which this application claims priority, is hereby incorporated herein by reference, in its entirety.

Aspects of the various embodiments described above can be combined to provide further embodiments. In general, in the following claims, the terms used should not be construed to limit the claims to the specific embodiments disclosed in the specification and the claims, but should be construed to include all possible embodiments along with the full scope of equivalents to which such claims are entitled.

1. A method for operating a switching element of an electrical component, the method comprising:
providing a time series of current strength values of an electrical current flowing in the electrical component registered in time steps that are consecutive, the electrical current being led through the switching element;
operating a thermal model of the electrical component, wherein the thermal model is a first order recursive filter that filters squared current strength values of the time series and generates, as a respective output value in each of the time steps, a presently estimated temperature value Tₙ, that is compared to a limit value;
determining a temperature of the electrical component from the current strength values using the thermal model; and
in response to determining that the temperature is greater than the limit value, switching the switching element to an electrically blocking state in which the electrical current is interrupted.

2. The method according to claim 1, wherein the filter contains a term for a power input that quantifies electrical power produced by a present squared current strength value i²ₙ of a present time step n.

3. The method according to claim 1, wherein the filter contains a term for heat dissipation from the electrical component, and the heat dissipation results from a characteristic value rₜₕ for a thermal resistance of a material of the electrical component.

4. The method according to claim 1, wherein the filter contains a mathematical term with an ambient temperature Tᵤₙ at a present time step n, and a value of the mathematical term is provided from measured values of the ambient temperature.

5. The method according to claim 1, wherein the filter normalizes at least one term to a sampling rate f of the time series, where the sampling rate is f=1/Δt and Δt is a time duration of the time steps.

6. The method according to claim 1, wherein the filter models a temperature-dependent material property of a material of the electrical component and uses an output value Tₙ₋₁ of a preceding time step as a present temperature of the material.

7. The method according to claim 1, wherein the filter includes specific parameters, and wherein each of the specific parameters indicates a length-related dimension.

8. The method according to claim 1, wherein the filter includes as parameters of the electrical component:
a specific thermal resistance rₜₕ,
an electrical conductivity σ,
a cross section area A,
a specific gravity ρ, and
a specific heat capacity
and the filter computes an output value Tₙ for the time steps n as:
$${T}_{n} = \frac{{T}_{un} + \frac{σ {r}_{th}}{A} {i}_{n}^{2} + c ρ {Ar}_{th} f {T}_{n - 1}}{1 + c ρ {Ar}_{th} f} with n = 1 , 2 , …$$
with T₀=Tᵤ₀ being an initial ambient temperature Tᵤ and Tᵤₙ being an ambient temperature Tᵤ measured at a respective time step n.

9. The method according to claim 8, wherein a heat storage capacity of an electrical insulation i of the electrical component and a heat storage capacity of a material k of the electrical component surrounded by the material k and electrically conducting the electrical current is factored into the filter by:
cρA=cₖρₖAₖ+cᵢρᵢAᵢ.

10. The method according to claim 1, wherein the electrical component is a cable.

11. The method according to claim 1, wherein the switching element is an electronic semiconductor switch.

12. A control circuit that controls a switching element of an electrical component, the control circuit comprising:
at least one processor; and
at least one memory storing program code that, when executed by the at least one processor, causes the at least one processor to:
provide a time series of current strength values of an electrical current flowing in the electrical component registered in time steps that are consecutive, the electrical current being led through the switching element;
operate a thermal model of the electrical component, wherein the thermal model is a first order recursive filter that filters squared current strength values of the time series and generates, as a respective output value in each of the time steps, a presently estimated temperature value Tₙ, that is compared to a limit value;
determine a temperature of the electrical component from the current strength values using the thermal model; and
in response to determining that the temperature is greater than the limit value, switch the switching element to an electrically blocking state in which the electrical current is interrupted.

13. An electrical component comprising:
a switching element; and
a control circuit coupled to the switching element,
wherein the control circuit includes:
at least one processor; and
at least one memory storing program code that, when executed by the at least one processor, causes the at least one processor to:
provide a time series of current strength values of an electrical current flowing in the electrical component registered in time steps that are consecutive, the electrical current being led through the switching element;
operate a thermal model of the electrical component, wherein the thermal model is a first order recursive filter that filters squared current strength values of the time series and generates, as a respective output value in each of the time steps, a presently estimated temperature value Tₙ, that is compared to a limit value;
determine a temperature of the electrical component from the current strength values using the thermal model; and
in response to determining that the temperature is greater than the limit value, switch the switching element to an electrically blocking state in which the electrical current is interrupted.
